(19) United States
(12) Patent Application Publication
(10) Pub. No.: US 2007/0126008 A1
(43) Pub. Date: Jun. 7, 2007

(54) Gallium nitride-based compound semiconductor light-emitting device, positive electrode for the device, light-emitting diode and lamp using the device

(76) Inventor: Munetaka Watanabe, Chiba (JP)

Correspondence Address: SUGHRUE MION, PLLC, 2100 PENNSYLVANIA AVENUE, N.W., SUITE 800, WASHINGTON, DC, 20037, US

(21) Appl. No.: 10/575,365

(22) PCT Filed: Oct. 13, 2004
(86) PCT No.: PCT/JP04/15447

§ 371 Date: Apr. 11, 2006

Related U.S. Application Data
(60) Provisional application No. 60/512,855, filed on Oct. 22, 2003.

(30) Foreign Application Priority Data
Oct. 14, 2003 (JP) 2003-354150

(51) Int. Cl. H01L 33/00

(52) U.S. Cl. 257/79

(57) ABSTRACT

An object of the present invention is to provide a flip-chip-type gallium nitride compound semiconductor light-emitting device exhibiting excellent ohmic characteristics, excellent bonding characteristics, and high emission output. The inventive flip-chip-type gallium nitride compound semiconductor light-emitting device comprises a positive electrode which has a three-layer structure comprising an ohmic electrode layer composed of rhodium which is in contact with the p-type semiconductor layer, an adhesion layer composed of titanium which is provided on the ohmic electrode layer and has a thickness of 10 Å or more, and a bonding pad layer provided on the adhesion layer and being composed of a metal selected from the group consisting of gold, aluminum, nickel, and copper, or composed of an alloy containing at least one of these metals.

### CROSS REFERENCE TO RELATED APPLICATION

This application is an application filed under 35 U.S.C. §111(a) claiming benefit pursuant to 35 U.S.C. §119(e)(1) of the filing date of the Provisional Application No. 60/512,855 filed on Oct. 22, 2003, pursuant to 35 U.S.C. §111(b).

### TECHNICAL FIELD

The present invention relates to a flip-chip-type gallium nitride compound semiconductor light-emitting device, to a light-emitting diode employing the device, and to a lamp employing the device. More particularly, the present invention relates to a flip-chip-type gallium nitride compound semiconductor light-emitting device including a positive electrode having high reflectance and low ohmic resistance.

### BACKGROUND ART

In recent years, a gallium nitride compound semiconductor represented by the formula AlₓGa_{y}In_{1-x-y}N (0≦x≦1, 0≦y≦1, x+y≦1) has become of interest as a material for producing a light-emitting diode (LED) which emits ultraviolet to blue light, or green light. Through employment of such a compound semiconductor, ultraviolet light, blue light, or green light of high emission intensity can be obtained; such high-intensity light has conventionally been difficult to attain. Unlike the case of a GaAs light-emitting device, such a gallium nitride compound semiconductor is generally grown on a sapphire substrate (i.e., an insulating substrate); hence, an electrode cannot be provided on the back surface of the substrate. Therefore, both a negative electrode and a positive electrode must be provided on semiconductor layers formed through crystal growth on the substrate.

In the case of the gallium nitride compound semiconductor device, the sapphire substrate is permeable with respect to emitted light. Therefore, attention is drawn to a flip-chip-type light-emitting device, which is configured by mounting the semiconductor device such that the electrodes face downward, whereby emitted light is extracted through the sapphire substrate.

FIG. 1 is a schematic representation showing a general structure of a flip-chip-type light-emitting device. Specifically, the light-emitting device includes a substrate 1, a buffer layer 2, an n-type semiconductor layer 3, a light-emitting layer 4, and a p-type semiconductor layer 5, the layers being formed atop the substrate through crystal growth. A portion of the light-emitting layer 4 and a portion of the p-type semiconductor layer 5 are removed through etching, thereby exposing a portion of the n-type semiconductor layer 3 to the outside. A positive electrode 10 is formed on the p-type semiconductor layer 5, and a negative electrode 20 is formed on the exposed portion of the n-type semiconductor layer. The light-emitting device is mounted on, for example, a lead frame such that the electrodes face the frame, followed by bonding. Therefore, the light emitted from the light-emitting layer 4 is extracted through the substrate 1. In this light-emitting device, in order to attain efficient extraction of light, the positive electrode 10 is formed of a reflective metal, and is provided so as to cover the majority of the p-type semiconductor layer 5, whereby the light emitted from the light-emitting layer toward the positive electrode is reflected by the positive electrode 10, and is also extracted through the substrate 1.

Accordingly, such a positive electrode is required to be formed of a material having low ohmic resistance and high reflectance. In connection with this requirement, there has been proposed a technique relating to a positive electrode formed of rhodium (e.g., Japanese Patent Application Laid-Open (kokai) No. 2000-183400). Specifically, this technique relates to a positive electrode having a structure including an ohmic electrode layer formed of platinum or rhodium (Rh), the layer being in contact with a p-type semiconductor layer, a second layer formed of gold (Au) and provided atop the ohmic electrode layer, and a third layer formed of titanium (Ti) or chromium and provided atop the second layer. The technique contemplates increasing the resistance of the Rh layer, and preventing exfoliation of an insulating layer (e.g., an SiO₂ layer) which is to be provided on the outermost layer of the electrode. However, the technique may fail to secure sufficient adhesion between the Rh layer and the Au layer, and thus exfoliation may occur at the interface between the Rh layer and the Au layer during the course of bonding. When the third layer is formed of Ti, sufficient adhesion between the third layer and Au balls or Au bumps may fail to be secured, whereby the resultant device cannot reliably pass a bond pull test or a shearing test. In addition, when the Ti layer is formed in the final film formation step, the vacuum in the film formation apparatus may be deteriorated due to the gettering effect of Ti.

As has been known, when an Ni layer (serving as an ohmic electrode) which is in contact with a p-type semiconductor layer, and a layer of Au serving as a bonding metal are laminated with each other by the mediation of a Ti layer, adhesion between the Ni layer and the Au layer is enhanced, thereby preventing exfoliation of the Ni and Au layers (e.g., Japanese Patent Application Laid-Open (kokai) No. 11-54843). However, the Ni layer exhibits a reflectance as low as about 30% at around 470 nm, and therefore is not suitable as a reflective electrode of a flip-chip-type light-emitting device. In addition, the Ni layer must be annealed for attaining low ohmic resistance, although an Rh layer does not require such annealing.

### DISCLOSURE OF INVENTION

In the case where Rh is employed as a positive electrode material, a critical issue is to secure adhesion between the resultant positive electrode and balls formed of gold wire which are employed during the course of bonding. In such a case, generally, an Au bonding pad is provided on the outermost layer of the positive electrode. However, difficulty is encountered in securing sufficient adhesion between the Rh electrode and the Au bonding pad without performance of thermal treatment. Meanwhile, when thermal treatment is performed, the ohmic resistance of the Rh electrode may increase as a result of diffusion of Au. In view of the foregoing, an object of the present invention is to provide a positive electrode of low ohmic resistance including an ohmic electrode layer formed of Rh, which exhibits high reflectance, the ohmic electrode layer being in contact with a p-type semiconductor layer, and a bonding pad layer formed of, for example, Au, wherein adhesion between the ohmic electrode layer and the bonding pad layer is enhanced.

The present invention provides the following.
(1) A flip-chip-type gallium nitride compound semiconductor light-emitting device comprising a substrate, an n-type semiconductor layer, a light-emitting layer, and a p-type semiconductor layer, a negative electrode provided on the n-type semiconductor layer, and a positive electrode provided on the p-type semiconductor layer, the layers being successively provided atop the substrate in this order and being composed of a gallium nitride compound semiconductor, wherein the positive electrode has a three-layer structure comprising an ohmic electrode layer composed of rhodium which is in contact with the p-type semiconductor layer, an adhesion layer composed of titanium which is provided on the ohmic electrode layer and has a thickness of 10 Å or more, and a bonding pad layer provided on the adhesion layer and being composed of a metal selected from the group consisting of gold, aluminum, nickel, and copper, or composed of an alloy containing at least one of these metals.
(2) A flip-chip-type gallium nitride compound semiconductor light-emitting device as described in (1) above, wherein the adhesion layer has a thickness of 500 Å to 3,000 Å.
(3) A flip-chip-type gallium nitride compound semiconductor light-emitting device as described in (2) above, wherein the adhesion layer has a thickness of 1,000 Å or more.
(4) A flip-chip-type gallium nitride compound semiconductor light-emitting device as described in any one of (1) through (3) above, wherein the ohmic electrode layer has a thickness of 100 Å to 3,000 Å.
(5) A flip-chip-type gallium nitride compound semiconductor light-emitting device as described in (4) above, wherein the ohmic electrode layer has a thickness of 500 Å to 2,000 Å.
(6) A flip-chip-type gallium nitride compound semiconductor light-emitting device as described in (1) through (5) above, wherein the bonding pad layer has a thickness of at least 1,000 Å.
(7) A flip-chip-type gallium nitride compound semiconductor light-emitting device as described in (6) above, wherein the bonding pad layer has a thickness of 3,000 Å to 5,000 Å.
(8) A flip-chip-type gallium nitride compound semiconductor light-emitting device as described in any one of (1) through (7) above, wherein the bonding pad layer is composed of gold.
(9) A positive electrode for use in a gallium nitride compound semiconductor light-emitting device, wherein the positive electrode has a three-layer structure comprising an ohmic electrode layer composed of rhodium which is brought into contact with a p-type semiconductor layer of the compound semiconductor light-emitting device, an adhesion layer composed of titanium which is provided on the ohmic electrode layer and has a thickness of 10 Å or more, and a bonding pad layer provided on the adhesion layer, the bonding pad layer being composed of a metal selected from the group consisting of gold, aluminum, nickel, and copper, or composed of an alloy containing at least one of these metals.
(10) A positive electrode for use in gallium nitride compound semiconductor light-emitting device as described in (9) above, wherein the adhesion layer has a thickness of 500 Å to 3,000 Å.
(11) A positive electrode for use in a gallium nitride compound semiconductor light-emitting device as described in (9) or (10) above, wherein the adhesion layer has a thickness of 1,000 Å or more.
(12) A light-emitting diode comprising a flip-chip-type gallium nitride compound semiconductor light-emitting device as recited in any one of (1) through (8) above.
(13) A lamp comprising a flip-chip-type gallium nitride compound semiconductor light-emitting device as recited in any one of (1) through (8) above.

According to the present invention, which is characterized by providing a Ti adhesion layer between an Rh ohmic electrode layer and a bonding pad layer composed of, for example, Au, even when no thermal treatment is performed, exfoliation of the layers constituting a positive electrode during the course of bonding can be prevented. Therefore, according to the present invention, there is obtained a gallium nitride compound semiconductor light-emitting device exhibiting excellent ohmic characteristics, excellent bonding characteristics, and high emission output.

When the thickness of the Ti adhesion layer is regulated to 1000 Å or more, excellent lift-off performance can be attained in an electrode formation process.

### BRIEF DESCRIPTION OF DRAWINGS

FIG. 1 is a schematic representation showing a general structure of a conventional flip-chip-type compound semiconductor light-emitting device.

FIG. 2 is a schematic representation showing an example of the flip-chip-type gallium nitride compound semiconductor light-emitting device of the present invention.

### BEST MODE FOR CARRYING OUT THE INVENTION

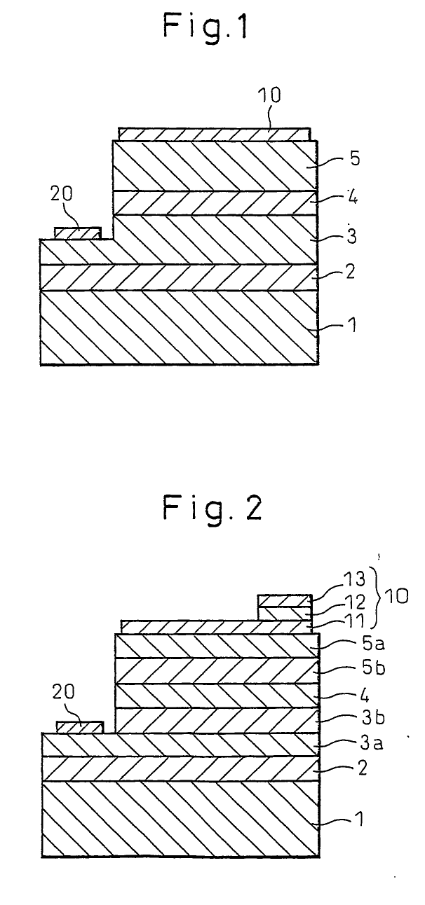

In the present invention, no particular limitations are imposed on the gallium nitride compound semiconductor layers stacked on a substrate, and the semiconductor stacked layers may be a conventionally known structure as shown in FIG. 1; i.e., a laminate including a buffer layer 2, an n-type semiconductor layer 3, a light-emitting layer 4, and a p-type semiconductor layer 5, the layers being formed atop a substrate 1 through crystal growth.

For example, the gallium nitride compound semiconductor laminate may be a laminate shown in FIG. 2, which includes a buffer layer 2 composed of an AlN layer, a contact layer 3a composed of an n-type GaN layer, a lower cladding layer 3b composed of an n-type GaN layer, a light-emitting layer 4 composed of an InGaN layer, an upper cladding layer 5b composed of a p-type AlGaN layer, and a contact layer 5a composed of a p-type GaN layer, the layers 2 through 5a being successively formed atop a sapphire substrate 1.

A portion of each of the following layers: the contact layer 5a, the upper cladding layer 5b, the light-emitting layer 4, and the lower cladding layer 3b, which layers constitute the aforementioned gallium nitride compound semiconductor laminate, is removed through etching, and subsequently a negative electrode 20 is provided on a portion of the contact layer 3a. No particular limitations are imposed on the material of the negative electrode, and the negative electrode may be formed of a conventionally known material such as titanium, aluminum, or chromium.

On the contact layer 5a is provided a positive electrode 10 according to the present invention, which electrode has a three-layer structure including an ohmic electrode layer 11 composed of rhodium (Rh), an adhesion layer 12 composed of titanium (Ti), and a bonding pad layer 13 composed of, for example, gold (Au). The Rh ohmic electrode layer, which is formed on the p-type GaN contact layer, serves as a reflective layer which efficiently reflects the light emitted from the light-emitting layer, and thus the emitted light can be extracted through the sapphire substrate in at high efficiency. Since the Ti adhesion layer is provided between the Rh ohmic electrode layer and the bonding pad layer composed of, for example, Au, even when alloying or thermal treatment is not performed after stacking of these layers, exfoliation of the layers constituting the positive electrode does not occur during the course of bonding.

In order to enhance reflection efficiency, preferably, the Rh ohmic electrode layer is provided so as to cover almost the entire surface of the contact layer 5a, such that the area of the electrode layer is increased to a maximum possible level. The thickness of the Rh ohmic electrode layer is preferably 100 to 3,000 Å. Particularly when the thickness is regulated to 500 to 3,000 Å, excellent reflection characteristics are obtained, which is preferable. Since Rh is an expensive material, when the thickness is regulated to 500 to 2,000 Å, production cost is reduced while excellent reflection characteristics are maintained, which is more preferable.

The Ti adhesion layer preferably has a thickness of 10 Å or more, more preferably 500 Å to 3,000 Å, most preferably 1,000 to 3,000 Å. When the thickness of the Ti adhesion layer is regulated to 1000 Å or more, excellent lift-off performance can be desirably attained in the electrode formation process. Particularly when a stacked film composed of a comparatively soft metallic material such as Rh or Au undergoes a lift-off process, the boundary between a portion peeled through lift-off and a remaining portion may become uneven by an occurrence of a burr, thereby causing failure such as undesirable leakage. In such a case, stacking of a hard metallic film such as Ti film having a considerable thickness would suppress the occurrence of a burr. However, when the film thickness is increased to 3,000 Å or more, film formation requires a long period of time, which is not preferred in the electrode formation process.

The bonding pad layer can be composed of a metal selected from the group consisting of Au, Al, Ni, and Cu, or composed of an alloy containing at least one of these metals. Preferably, the bonding pad layer is composed of Au or an Au-containing alloy. The bonding pad layer preferably has a thickness of 1,000 to 10,000 Å. In consideration of the characteristics of the bonding pad layer, the greater the thickness of the layer, the more enhanced the effect of the layer. However, from the viewpoint of production cost, more preferably, the thickness of the layer is regulated to 3,000 to 5,000 Å, which range ensures the functions as a bonding pad.

The bonding pad layer may have the same dimensions as those of the ohmic electrode layer. Alternatively, the bonding pad layer may be provided atop a portion of the ohmic electrode layer. When the bonding pad layer is provided atop a portion of the ohmic electrode layer, generally, the dimensions of the adhesion layer are regulated to be equal to those of the bonding pad layer. When the bonding pad layer has the same dimensions as those of the ohmic electrode layer, there is increased the degree of freedom in layout of bumps formed on a submount during the course of mounting of the light-emitting device. When the bonding pad layer is provided so as to cover the entire surface of the ohmic electrode layer, adhesion between these layers is envisaged to be further enhanced.

In the present invention, no particular limitations are imposed on the method for growing a gallium nitride compound semiconductor, and there may be employed any known method for growing a gallium nitride compound semiconductor, such as MOCVD (metal organic chemical vapor deposition), HVPE (hydride vapor phase epitaxy), or MBE (molecular beam epitaxy). From the viewpoints of layer thickness controllability and mass productivity, MOCVD is preferably employed. In the case where the gallium nitride compound semiconductor is grown by means of MOCVD, hydrogen (H₂) or nitrogen (N₂) is employed as a carrier gas, trimethylgallium (TMG) or triethylgallium (TEG) is employed as a Ga source, trimethylaluminum (TMA) or triethylaluminum (TEA) is employed as an Al source, trimethylindium (TMI) or triethylindium (TEI) is employed as an In source, and ammonia (NH₃), hydrazine (N₂H₄), or the like is employed as a nitrogen source. In addition, monosilane (SiH₄) or disilane (Si₂H₆) serving as an Si source, or germane (GeH₄) serving as a Ge source is employed as an n-type dopant, whereas bis(cyclopentadienyl)magnesium (Cp₂Mg) serving as an Mg source is employed as a p-type dopant. The gallium nitride compound semiconductor is grown by use of these raw materials under conventionally known appropriate conditions.

No particular limitations are imposed on the method for forming the metallic layers constituting the positive electrode, and the layers may be formed by means of a conventionally known method, such as resistance heating deposition, electron beam heating deposition, or sputtering. All the metallic layers may be formed by means of one single method. Alternatively, the metallic layers may be formed through the following procedure: forming a first metallic layer by means of a certain method in an apparatus; removing the resultant product from the apparatus; and stacking a subsequent layer through another method.

### EXAMPLE

The present invention will next be described in more detail by way of example, which should not be construed as limiting the invention thereto.

FIG. 2 is a cross-sectional view showing a gallium nitride compound semiconductor light-emitting device produced in the present Example.

The gallium nitride compound semiconductor stacked structure constituting the light-emitting device was produced through the following procedure: an AlN buffer layer 2 was formed on a sapphire substrate 1; and an n-type GaN contact layer 3a, an n-type GaN lower cladding layer 3ban InGaN light-emitting layer 4, a p-type AlGaN upper cladding layer 5b, and a p-type GaN contact layer Sa were successively formed atop the buffer layer 2. The contact layer 3a is composed of n-type GaN doped with Si (7×10¹⁸/cm³), the lower cladding layer 3b is composed of n-type GaN doped with Si (5×10¹⁸/cm³), and the light-emitting layer 4, having a single quantum well structure, is composed of In_{0.95}Ga_{0.05}N. The upper cladding layer 5b is composed of p-type Al_{0.25}Ga_{0.75}N doped with Mg (1×10¹⁸/cm³). The contact layer 5a is composed of p-type GaN doped with Mg (5×10¹⁹/cm³). Stacking of these layers was performed by means of MOCVD under typical conditions which are well known in the art.

A positive electrode and a negative electrode were provided on the contact layers 5a and 3a of the gallium nitride compound semiconductor stacked structure, respectively, through the below-described procedure, to thereby fabricate the light-emitting device.
(1) Firstly, an etching mask was formed on the contact layer 5a through the following procedure. A resist was uniformly applied onto the layer 5a, and the resist applied onto the region to be etched was removed through a known lithography technique.

The etching mask serves as a layer for protecting the contact layer 5a from any damage by plasma employed in reactive ion dry etching.
(2) Subsequently, the resultant product was subjected to reactive ion dry etching in a dry etching apparatus until a portion of the n-type GaN contact layer 3a was exposed to the outside. Thereafter, the resultant product was removed from the dry etching apparatus, and the resist formed in the above step were removed by use of acetone. The dry etching was performed for forming the below-described negative electrode of the semiconductor light-emitting device.
(3) Thereafter, a resist was uniformly applied again onto the layer 5a and 3a, which were exposed to the outside, and an aperture for forming an ohmic electrode layer was provided, through photolithography, on a portion of the layer 5aand an Rh ohmic electrode layer (thickness: 2,000 Å) was formed through electron beam deposition. Thereafter, the metal deposits formed on the region other than the ohmic electrode layer region were removed through a lift-off technique together with the resist.

The Rh ohmic electrode layer formed through the above procedure was found to exhibit a reflectance of about 65% or more, when light of 460 nm was caused to be transmitted through the substrate. The contact resistivity of the Rh ohmic electrode layer was found to be 2 to 3×10⁻³ Ωcm² as measured by means of circular TLM.
(4) Subsequently, a resist was uniformly applied again, and then an aperture for forming an adhesion layer and a bonding pad layer was provided on a portion of the ohmic electrode layer through a known photolithography technique. Thereafter, a Ti adhesion layer (thickness: 1,000 Å) and an Au bonding pad layer (thickness: 2,000 Å) were formed through electron beam deposition and resistance heating deposition, respectively. Thereafter, the metal deposits formed on the region other than the bonding pad layer region were removed through a lift-off technique together with the resist.

In the above lift-off step, processing was continued consistently without causing peeling of an electrode or insufficient peeling of an unnecessary portion attributable to lift-off failure, and without causing a decrease in yield which would otherwise caused by any failure such as an undesirable lift-off pattern.
(5) Subsequently, a resist was uniformly applied again, and then an aperture for forming a negative electrode was provided, through a known photolithography technique, on the above-exposed portion of the n-type GaN contact layer 3a, which portion had been formed through reactive ion dry etching. Thereafter, a Ti layer (thickness: 1,000 Å) and an Au layer (thickness: 3,000 Å) were formed through electron beam deposition and resistance heating deposition, respectively. Thereafter, the metal deposits formed on the region other than the region where these layers were formed were removed through a lift-off technique together with the resist, to thereby form a negative electrode. The negative electrode, whose outermost layer is composed of Au, serves as a bonding pad.

The thus-produced semiconductor light-emitting device was cut into chips, and each chip was flip-chip-mounted on a submount. The resultant product was mounted on a TO-18 stem, followed by wiring, to thereby produce a light-emitting device product.

The thus-produced light-emitting device product exhibited an emission output of 6 mW and a forward voltage of 3.4 V at a current of 20 mA.

In order to evaluate the adhesion conditions between the layers of the positive electrode of the above-produced light-emitting device, an Au wire (diameter: 25 μm) was bonded onto the Au bonding pad layer such that the diameter of a ball portion formed during bonding became 100 to 110 μm, and then a bond pull test was performed under application of a tensile load of 55 g. As a result, the percentage of failure products was found to be 10% or less.

In the present Example, the bonding pad layer 13 was composed of Au. However, the bonding pad layer may be composed of Al, Ni, or Cu. In such a case, from the viewpoint of mounting performance, the outermost layer of the negative electrode (bonding pad) is preferably composed of the same metal as that constitutes the bonding pad layer of the positive electrode.

### INDUSTRIAL APPLICABILITY

The flip-chip-type gallium nitride compound semiconductor light-emitting device provided by the present invention is useful as a component for producing a light-emitting diode, a lamp, or a similar device.

1. A flip-chip-type gallium nitride compound semiconductor light-emitting device comprising a substrate, an n-type semiconductor layer, a light-emitting layer, and a p-type semiconductor layer, a negative electrode provided on said n-type semiconductor layer, and a positive electrode provided on said p-type semiconductor layer, the layers being successively provided atop said substrate in this order and being composed of a gallium nitride compound semiconductor, wherein said positive electrode has a three-layer structure comprising an ohmic electrode layer composed of rhodium which is in contact with said p-type semiconductor layer, an adhesion layer composed of titanium which is provided on said ohmic electrode layer and has a thickness of 10 Å or more, and a bonding pad layer provided on said adhesion layer and being composed of a metal selected from the group consisting of gold, aluminum, nickel, and copper, or composed of an alloy containing at least one of these metals.

2. A flip-chip-type gallium nitride compound semiconductor light-emitting device according to claim 1, wherein said adhesion layer has a thickness of 500 Å to 3,000 Å.

3. A flip-chip-type gallium nitride compound semiconductor light-emitting device according to claim 2, wherein said adhesion layer has a thickness of 1,000 Å or more.

4. A flip-chip-type gallium nitride compound semiconductor light-emitting device according to claim 1, wherein said ohmic electrode layer has a thickness of 100 Å to 3,000 Å.

5. A flip-chip-type gallium nitride compound semiconductor light-emitting device according to claim 4, wherein said ohmic electrode layer has a thickness of 500 Å to 2,000 Å.

6. A flip-chip-type gallium nitride compound semiconductor light-emitting device according to claim 1, wherein said bonding pad layer has a thickness of at least 1,000 Å.

7. A flip-chip-type gallium nitride compound semiconductor light-emitting device according to claim 6, wherein said bonding pad layer has a thickness of 3,000 Å to 5,000 Å.

8. A flip-chip-type gallium nitride compound semiconductor light-emitting device according to claim 1, wherein said bonding pad layer is composed of gold.

9. A positive electrode for use in a gallium nitride compound semiconductor light-emitting device, wherein said positive electrode has a three-layer structure comprising an ohmic electrode layer composed of rhodium which is brought into contact with a p-type semiconductor layer of said compound semiconductor light-emitting device, an adhesion layer composed of titanium which is provided on said ohmic electrode layer and has a thickness of 10 Å or more, and a bonding pad layer provided on said adhesion layer, said bonding pad layer being composed of a metal selected from the group consisting of gold, aluminum, nickel, and copper, or composed of an alloy containing at least one of these metals.

10. A positive electrode for use in gallium nitride compound semiconductor light-emitting device according to claim 9, wherein said adhesion layer has a thickness of 500 Å to 3,000 Å.

11. A positive electrode for use in a gallium nitride compound semiconductor light-emitting device according to claim 9, wherein said adhesion layer has a thickness of 1,000 Å or more.

12. A light-emitting diode comprising a flip-chip-type gallium nitride compound semiconductor light-emitting device according to claim 1.

13. A lamp comprising a flip-chip-type gallium nitride compound semiconductor light-emitting device according to claim 1.
